(19) United States
(12) Patent Application Publication
(10) Pub. No.: US 2015/0187797 A1
(43) Pub. Date: Jul. 2, 2015

(54) Array Substrate Common Electrode Structure, the Manufacturing Method Thereof, and Array Substrate

(71) Applicant: Shenzhen China Star Optoelectronics Technology Co. Ltd., Shenzhen, Guangdong (CN)

(72) Inventor: Xiangyang Xu, Shenzhen (CN)

(73) Assignee: Shenzhen China Star Optoelectronics Technology Co. Ltd., Shenzhen, Guangdong (CN)

(21) Appl. No.: 14/240,709

(22) PCT Filed: Jan. 9, 2014
(86) PCT No.: PCT/CN2014/070376

§ 371 Date: Feb. 24, 2014

(30) Foreign Application Priority Data
Dec. 26, 2013 (CN) 201310730040.7

(51) Int. Cl. H01L 27/12; H01L 29/417; H01L 29/423; H01L 21/28; H01L 21/283

(52) U.S. Cl. CPC H01L 27/124; H01L 27/1259; H01L 21/28008; H01L 21/283; H01L 29/42384; H01L 29/41733

(57) ABSTRACT

The present invention discloses an array substrate common electrode structure, the manufacturing method thereof, and an array substrate. The array substrate common electrode structure comprises: a pair of banded gate metals arranged laterally and parallel to each other, a pair of banded source-drain metals arranged vertically and perpendicularly connected to the gate metal, and at least one common electrode line made of the same layer metal as the source-drain metal, the common electrode line being arranged vertically, and the two ends thereof being connected with the gate metal. In the present invention, the common electrode line used as storage capacitor is made of the same layer metal as the source-drain metal, so that the storage capacitor dielectric layer only comprises a passivation insulating protective layer. Therefore, it can greatly decrease the width of the common electrode line, increase the opening ratio of the panel, and further reduce the power consumption of LED backlight without decreasing storage capacitor.

This application is claiming a priority arisen from a patent application, entitled with “Array Substrate Common Electrode Structure, the Manufacturing Method Thereof, and Array Substrate”, submitted to China Patent Office on Dec. 26, 2013, designated with an Application Number 201310730040.7. The whole and complete disclosure of such patent application is hereby incorporated by reference. This application also related to National Stage Application No.: ______ (Attorney Docket No. CP14012), submitted on the same date, entitled, “Liquid Crystal Display Touch Screen Array Substrate and the Corresponding Liquid Crystal Display Touch Screen”; National Stage Application No.: ______ (Attorney Docket No. CP14013), submitted on the same date, entitled, “Liquid Crystal Display Touch Screen Array Substrate and the Corresponding Liquid Crystal Display Touch Screen”; National Stage Application No.: ______ (Attorney Docket No. CP14014), submitted on the same date, entitled, “Embedded Touch Array Substrate and Liquid Crystal Display Panel” assigned to the same assignee.

### BACKGROUND OF THE INVENTION

1. Field of the Invention

The present invention relates to the technology fields of image display, and in particular to an array substrate common electrode structure, the manufacturing method thereof, and an array substrate.

2. The Related Arts

Recently, liquid crystal display (LCD) technology has developed rapidly. It has made great progress from the size of the screen to the display quality. LCD has several characteristics of small size, low power consumption, and no radiation, which has dominated the field of flat panel display.

With the development of display technology, people have become increasingly demanding visual enjoyment, which is mainly reflected in the resolution, brightness, color, refresh rate, visual angle, etc. In addition, the power consumption is also an important indicator to measure the quality of liquid crystal displays.

The power consumption of the liquid crystal display is divided into two parts. One is logic power consumption of panel, and the other is power consumption of LED backlight. Wherein, the power consumption of LED backlight is the main power consumption of the liquid crystal display. The power consumption of LED backlight mainly depends on the size and the opening ratio of the panel. The larger size of the panel is, the more power consumption of LED backlight is. The higher opening ratio of the panel is, the lower power consumption of LED is. The opening ratio of the panel depends on material, resolution and panel circuit design. The material and resolution depends on the price of the panel, while the panel circuit design is more flexible.

Referring to Figure, it shows the schematic circuit of a conventional TFT panel, which comprises: a gate scanning line 1′ and a data line 2′ arranged alternately, a pixel switch TFT 3′ electrically connected with the gate scanning line 1′ and the data line 2′, a storage capacitor Cst, a liquid capacitor Clc, and a common electrode COM. The common electrode comprises two parts. One is a storage capacitor COM electrode located at the TFT side, and the other is a liquid capacitor COM electrode located at the CF side (the display modes of twisted nematic TN and vertically aligned VA). The COM electrode at the TFT side is manly used as storage capacitor. The conventional COM electrode 4′ is shown in FIG. 2, and the wiring structure of the array substrate is shown in FIG. 3. The COM line 43′ used as storage capacitor is mainly made of the same layer metal as the gate metal. However, the structure of the storage capacitor dielectric layer comprises a gate insulating layer and a passivation layer insulating protection. Therefore, in order to ensure sufficient storage capacitor, the width of the COM line 43′ is usually larger, which restricts the increase in opening ratio.

### SUMMARY OF THE INVENTION

The technical issue to be solved by the present invention is to provide an array substrate common electrode structure, the manufacturing method thereof, and an array substrate.

In order to solve the technical issue, the present invention provides an array substrate common electrode structure, which comprises: a pair of banded gate metals arranged laterally and parallel to each other, a pair of banded source-drain metals arranged vertically and perpendicularly connected to the gate metal, and at least one common electrode line made of the same layer metal as the source-drain metal, the common electrode line being arranged vertically, and the two ends thereof being connected with the gate metal.

Wherein, multiple said common electrode lines are equally spaced from each other.

Wherein, the common electrode line is parallel to the source-drain metal.

The present invention further provides an array substrate, which comprises: a common electrode structure, multiple gate scanning lines and data lines arranged alternately; wherein, the common electrode structure comprises: a pair of banded gate metals arranged laterally and parallel to each other, a pair of banded source-drain metals arranged vertically and perpendicularly connected to the gate metal, and at least one common electrode line made of the same layer metal as the source-drain metal, the common electrode line being arranged vertically, and the two ends thereof being connected with the gate metal.

Wherein, multiple said common electrode lines are equally spaced from each other.

Wherein, the common electrode line is parallel to the source-drain metal.

The present invention further provides a manufacturing method of array substrate common electrode structure, comprising:
step S1, providing a pair of gate metals arranged laterally and parallel to each other;
step S2, providing a pair of source-drain metals arranged vertically and perpendicularly connected to the gate metal; and
step S3, providing at least one common electrode line made of the same layer metal as the source-drain metal, the common electrode line being arranged vertically, and the two ends thereof being connected with the gate metal.

Wherein, multiple said common electrode lines are equally spaced from each other.

Wherein, the common electrode line is parallel to the source-drain metal.

In the embodiment of the present invention, the common electrode line used as storage capacitor is made of the same layer metal as the source-drain metal, so that the storage capacitor dielectric layer only comprises a passivation insulating protective layer. Therefore, it can greatly decrease the width of the common electrode line, increase the opening ratio of the panel, and further reduce the power consumption of LED backlight without decreasing storage capacitor.

### BRIEF DESCRIPTION OF THE DRAWINGS

In order to more clearly illustrate the embodiment of the present invention or the technical issue of the prior art, the accompanying drawings and the detailed descriptions are as follows. Obviously, the following description of the accompanying drawings are only some embodiments according to the present invention, for persons of ordinary skill in this field, they can also obtain other drawings based on these drawings without creative effort.

FIG. 1 is a schematic view illustrating the simplified circuit of a TFT-LCD array substrate according to the existing technology;

FIG. 2 is a schematic view illustrating the structure of a common electrode according to the existing technology;

FIG. 3 is a schematic view illustrating the structure of the wiring structure of the array substrate according to the existing technology;

FIG. 4 is a schematic view illustrating the structure of an array substrate common electrode according to the embodiment of the present invention;

FIG. 5 is a schematic view illustrating the wiring structure of the array substrate of the common electrode according to the embodiment of the present invention; and

FIG. 6 is schematic flow of the manufacturing method of array substrate common electrode structure according to the embodiment of the present invention.

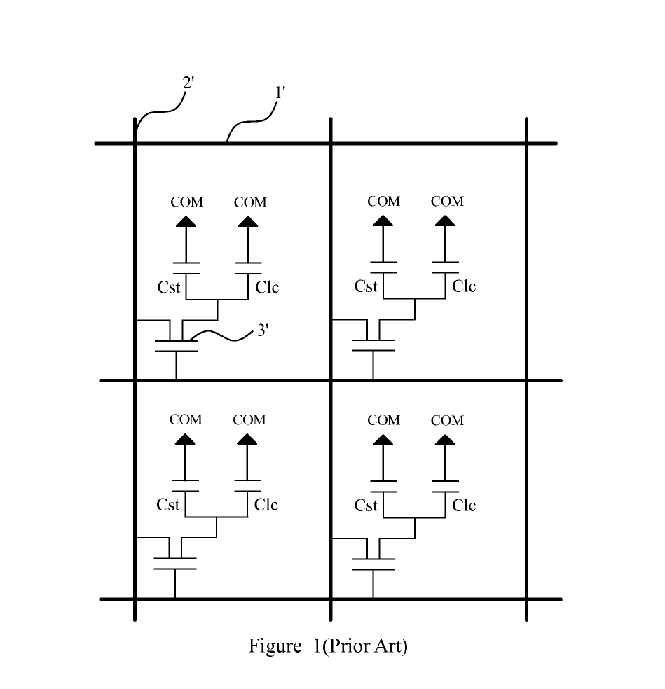

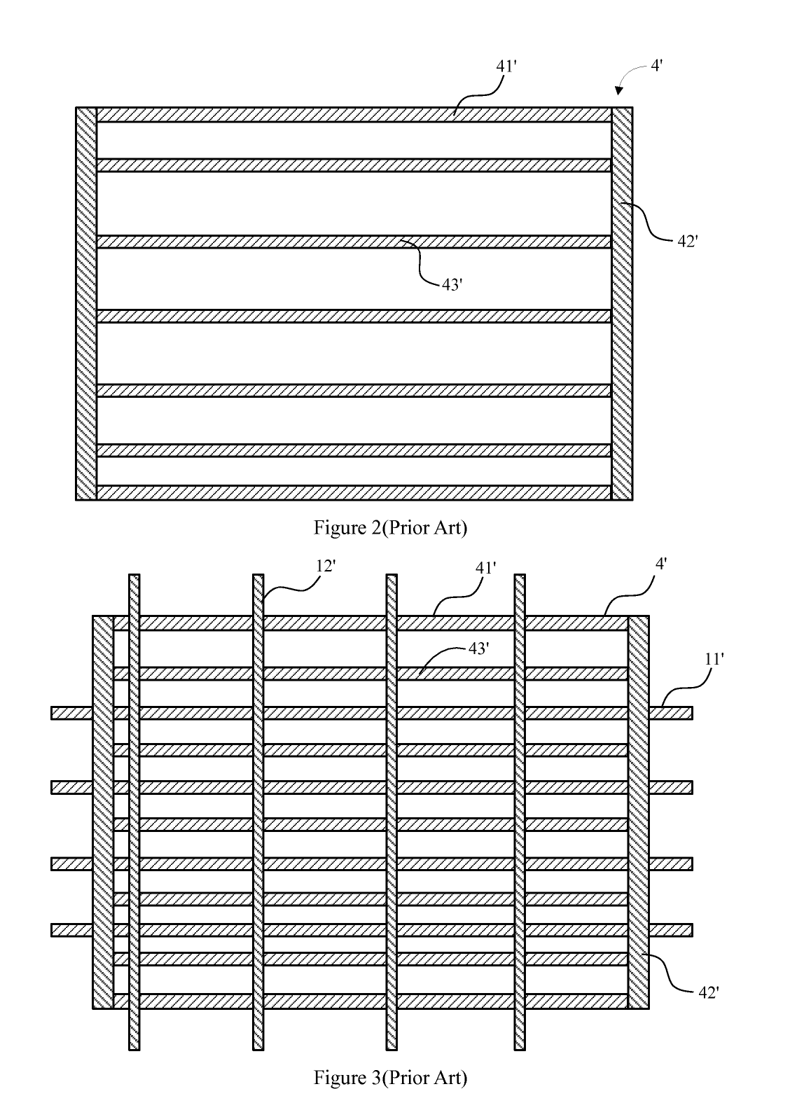

### DETAILED DESCRIPTION OF THE PREFERRED EMBODIMENTS

The following description of the embodiments with reference to the attached drawings, the present invention may be used to illustrate the specific embodiments to implement. The present invention mentioned directional terms, such as “upper”, “lower”, “front”, “rear”, “Left”, “Right”, “top”, “bottom”, “horizontal”, “vertical”, etc. only with reference to the accompanying drawings, in the direction. Therefore, the use of directional terms are used to describe and understand the present invention and not intended to limit the present invention.

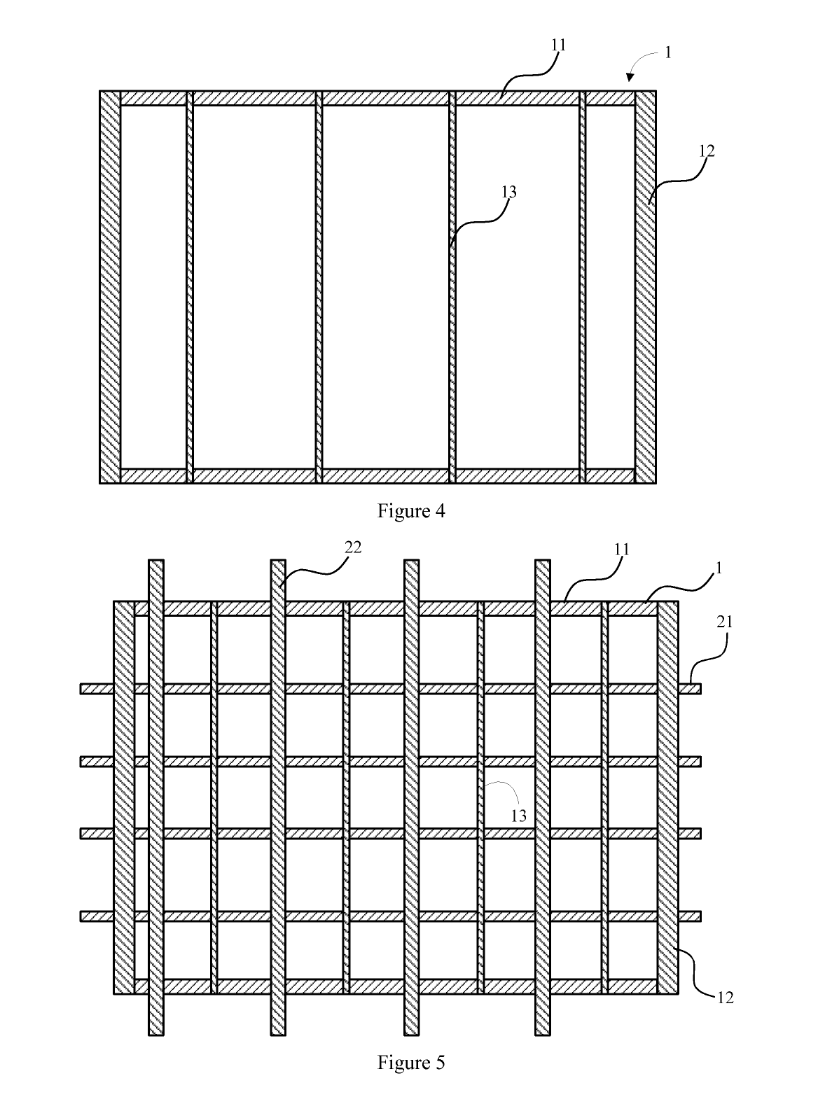

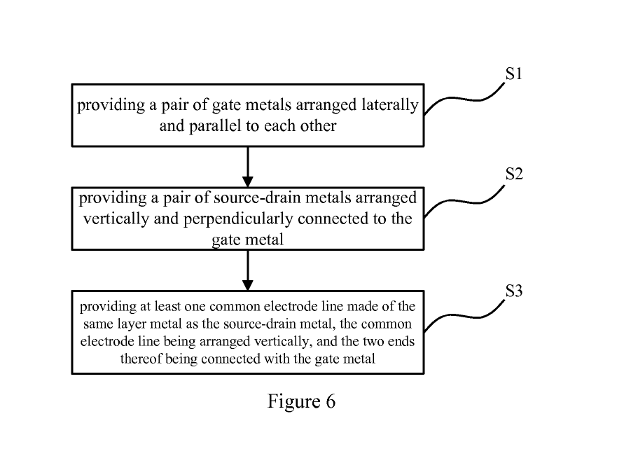

Referring to FIG. 4, the embodiment of the present invention provides an array substrate common electrode structure 1, which comprises: a pair of banded gate metals 11 arranged laterally and parallel to each other, a pair of banded source-drain metals 12 arranged vertically and perpendicularly connected to the gate metal 11, and at least one common electrode line 13 made of the same layer metal as the source-drain metal 12, the common electrode line 13 being arranged vertically, and the two ends thereof being connected with the gate metal 11.

Specifically, multiple said common electrode lines 13 are equally spaced from each other, and are parallel to the source-drain metal 12.

The common electrode line 13 according to the present embodiment will be used as storage capacitor, which is made of the same layer metal as the source-drain metal 12. The storage capacitor dielectric layer with this structure only comprises a passivation insulating protective layer. Therefore, it can greatly decrease the width of the common electrode line 13, increase the opening ratio of the panel, and further reduce the power consumption of LED backlight without decreasing storage capacitor.

Referring to FIG. 5, corresponding to the array substrate common electrode structure according to the first embodiment of the present invention, the second embodiment of the present invention provides an array substrate, which comprises: a common electrode structure 1, multiple gate scanning lines 21 and data lines 22 arranged alternately; wherein, the common electrode structure 1 comprises: a pair of banded gate metals 11 arranged laterally and parallel to each other, a pair of banded source-drain metals 12 arranged vertically and perpendicularly connected to the gate metal 11, and at least one common electrode line 13 made of the same layer metal as the source-drain metal 12; the common electrode line 13 is arranged vertically, and the two ends thereof are connected with the gate metal 11; the gate scanning lines 21 are parallel to the gate metal 11, and are provided between the two gate metals 11 with intervals; the data lines 22 are parallel to the common electrode line 13 and arranged with intervals.

Specifically, multiple said common electrode lines 13 are equally spaced from each other, and are parallel to the source-drain metal 12.

Corresponding to the array substrate common electrode structure according to the first embodiment of the present invention, the third embodiment of the present invention provides a manufacturing method of array substrate common electrode structure, comprising:
step S1, providing a pair of gate metals arranged laterally and parallel to each other;
step S2, providing a pair of source-drain metals arranged vertically and perpendicularly connected to the gate metal; and
step S3, providing at least one common electrode line made of the same layer metal as the source-drain metal, the common electrode line being arranged vertically, and the two ends thereof being connected with the gate metal.

Specifically, multiple said common electrode lines are equally spaced from each other, and are parallel to the source-drain metal.

The specific structure and the corresponding technology about the array substrate common electrode structure according to the present embodiment can refer to the illustration of the first embodiment and FIGS. 4 to 5, which is not repeated here.

In the present embodiment, the common electrode line used as storage capacitor is made of the same layer metal as the source-drain metal, so that the storage capacitor dielectric layer only comprises a passivation insulating protective layer. Therefore, it can greatly decrease the width of the common electrode line, increase the opening ratio of the panel, and further reduce the power consumption of LED backlight without decreasing storage capacitor.

The preferred embodiments according to the present invention are mentioned above, which cannot be used to define the scope of the right of the present invention. Those modifications and variations are considered encompassed in the scope of protection defined by the clams of the present invention.

What is claimed is:

1. An array substrate common electrode structure (1), which comprises: a pair of banded gate metals (11) arranged laterally and parallel to each other, a pair of banded source-drain metals (12) arranged vertically and perpendicularly connected to the gate metal (11), and at least one common electrode line (13) made of the same layer metal as the source-drain metal (12), the common electrode line (13) being arranged vertically, and the two ends thereof being connected with the gate metal (11).

2. The array substrate common electrode structure as claimed in claim 1, wherein multiple said common electrode lines (13) are equally spaced from each other.

3. The array substrate common electrode structure as claimed in claim 1, wherein the common electrode line (13) is parallel to the source-drain metal (12).

4. An array substrate, which comprises: a common electrode structure (1), multiple gate scanning lines (21) and data lines (22) arranged alternately; wherein, the common electrode structure (1) comprises: a pair of banded gate metals (11) arranged laterally and parallel to each other, a pair of banded source-drain metals (12) arranged vertically and perpendicularly connected to the gate metal (11), and at least one common electrode line (13) made of the same layer metal as the source-drain metal (12), the common electrode line (13) being arranged vertically, and the two ends thereof being connected with the gate metal (11).

5. The array substrate as claimed in claim 4, wherein multiple said common electrode lines (13) are equally spaced from each other.

6. The array substrate as claimed in claim 4, wherein the common electrode line (13) is parallel to the source-drain metal (12).

7. A manufacturing method of array substrate common electrode structure, comprising:
step S1, providing a pair of gate metals arranged laterally and parallel to each other;
step S2, providing a pair of source-drain metals arranged vertically and perpendicularly connected to the gate metal; and
step S3, providing at least one common electrode line made of the same layer metal as the source-drain metal, the common electrode line being arranged vertically, and the two ends thereof being connected with the gate metal.

8. The manufacturing method as claimed in claim 7, wherein multiple said common electrode lines are equally spaced from each other.

9. The manufacturing method as claimed in claim 7, wherein the common electrode line is parallel to the source-drain metal.
